(19) United States
(12) Patent Application Publication
(10) Pub. No.: US 2026/0052347 A1
(43) Pub. Date: Feb. 19, 2026

(54) LOUDSPEAKER

(71) Applicant: MERRY ELECTRONICS (SUZHOU) CO., LTD., Suzhou City (CN)

(72) Inventors: Chunlong ZHENG, Suzhou City (CN); Mingya LUO, Suzhou City (CN)

(73) Assignee: MERRY ELECTRONICS (SUZHOU) CO., LTD., Suzhou City (CN)

(21) Appl. No.: 18/928,955

(22) Filed: Oct. 28, 2024

(30) Foreign Application Priority Data
Aug. 19, 2024 (CN) 202411133461.6

(51) Int. Cl. H04R 17/00; H04R 7/12; H10N 30/20

(52) U.S. Cl. CPC H04R 17/00; H04R 7/127; H10N 30/2045

(57) ABSTRACT

A loudspeaker includes a support frame, a first diaphragm assembly, a second diaphragm assembly, a first vibration assembly, and a second vibration assembly; the first vibration assembly includes a first piezoelectric cantilever, the first piezoelectric cantilever includes a first fixed end connected to the support frame and a first free end suspended inside the support frame and connected to the first diaphragm assembly; the second vibration assembly includes a second piezoelectric cantilever, the second piezoelectric cantilever includes a second fixed end connected to the support frame and a second free end suspended inside the support frame and connected to the second diaphragm assembly; the first piezoelectric cantilever and the second piezoelectric cantilever are disposed opposite each other in a first direction, and the length of the first piezoelectric cantilever is different from the length of the second piezoelectric cantilever in the second direction perpendicular to the first direction.

### CROSS-REFERENCE TO RELATED APPLICATION(S)

This application claims priority to Chinese Patent Application No. 202411133461.6 filed Aug. 19, 2024, the disclosure of which is incorporated herein by reference in its entirety.

### TECHNICAL FIELD

The present disclosure relates to the field of loudspeakers and, in particular, to a loudspeaker.

### BACKGROUND

A loudspeaker, as an important electro-acoustic device, has been widely used in an electronic device. The loudspeaker can be divided into a moving-coil loudspeaker, a moving-iron loudspeaker, and a piezoelectric loudspeaker according to the type of technology. The piezoelectric loudspeaker has the advantages of being small, thin, lightweight, and free of magnetic field interference compared to the moving-coil loudspeaker.

In the related art, the piezoelectric loudspeaker includes a piezoelectric plate and a diaphragm connected to the piezoelectric plate. The piezoelectric plate vibrates under a drive voltage to drive the diaphragm to vibrate, thereby enabling the loudspeaker to produce sound. To further improve the acoustic performance of the loudspeaker, two diaphragms in opposite positions are disposed, two piezoelectric plates are also disposed, the two piezoelectric plates and the two diaphragms are in a one-to-one correspondence, and each piezoelectric plate is used for driving its corresponding diaphragm to vibrate to produce sound. However, since the piezoelectric plate itself has various vibration modes, the frequency response curve of the loudspeaker will have a large number of peaks and valleys when the vibration modes of the two piezoelectric plates are superimposed, thereby resulting in the poor acoustic performance of the loudspeaker.

Therefore, a loudspeaker having excellent acoustic performance is urgently needed.

### SUMMARY

The present disclosure provides a loudspeaker.

The loudspeaker includes a support frame, a first diaphragm assembly, a second diaphragm assembly, a first vibration assembly, and a second vibration assembly.

The first diaphragm assembly is disposed in the support frame.

The second diaphragm assembly is disposed in the support frame and opposite the first diaphragm assembly in a first direction.

The first vibration assembly is located between the first diaphragm assembly and the second diaphragm assembly in the first direction and includes a first piezoelectric cantilever. The first piezoelectric cantilever includes a first fixed end and a first free end. The first fixed end is connected to the support frame, and the first free end is suspended inside the support frame and connected to the first diaphragm assembly.

The second vibration assembly is located between the second diaphragm assembly and the first vibration assembly in the first direction and includes a second piezoelectric cantilever. The second piezoelectric cantilever includes a second fixed end and a second free end. The second fixed end is connected to the support frame, and the second free end is suspended from the inner side of the support frame and connected to the second diaphragm assembly.

The first piezoelectric cantilever and the second piezoelectric cantilever are disposed opposite each other in the first direction, the length of the first piezoelectric cantilever in the second direction is different from the length of the second piezoelectric cantilever in the second direction, and the second direction is perpendicular to the first direction.

In some embodiments, multiple first piezoelectric cantilevers and multiple second piezoelectric cantilevers are disposed in a one-to-one correspondence in the loudspeaker, the multiple first piezoelectric cantilevers are disposed in the same layer and spaced from each other, and the multiple second piezoelectric cantilevers are disposed in the same layer and spaced from each other.

A first piezoelectric cantilever and a respective one second piezoelectric cantilever are disposed opposite each other in the first direction, and the length of the first piezoelectric cantilever in the second direction is different from the length of the respective one second piezoelectric cantilever in the second direction.

In some embodiments, two first piezoelectric cantilevers and two second piezoelectric cantilevers are disposed in a one-to-one correspondence in the loudspeaker, the two first piezoelectric cantilevers are spaced in the second direction, and the two second piezoelectric cantilevers are spaced in the second direction.

In some embodiments, the loudspeaker further includes a first connecting member, a second connecting member, a first support member, and a second support member.

One end of the first connecting member is connected to the first free end, and the first support member is connected between the first connecting member and the first diaphragm assembly.

One end of the second connecting member is connected to the second free end, and the second support member is connected between the second connecting member and the second diaphragm assembly.

In some embodiments, the first piezoelectric cantilever includes a first substrate and a first piezoelectric element disposed on at least one side of the first substrate in the thickness direction of the first substrate. One end of the first substrate is connected to the support frame. The first connecting member is connected to one end, facing away from the support frame, of the first piezoelectric element. The second piezoelectric cantilever includes a second substrate and a second piezoelectric element disposed on at least one side of the second substrate in the thickness direction of the second substrate. One end of the second substrate is connected to the support frame. The second connecting member is connected to one end, facing away from the support frame, of the second piezoelectric element.

In some embodiments, the first piezoelectric cantilever includes a first substrate and a first piezoelectric element disposed on at least one side of the first substrate in the thickness direction of the first substrate. One end of the first substrate is connected to the support frame, and the other end of the first substrate extends in a direction facing away from the support frame and forms the first connecting member. The second piezoelectric cantilever includes a second substrate and a second piezoelectric element disposed on at least one side of the second substrate in the thickness direction of the second substrate. One end of the second substrate is connected to the support frame, and the other end of the second substrate extends in the direction facing away from the support frame and forms the second connecting member.

In some embodiments, two ends of the first connecting member are connected in a one-to-one correspondence to two first free ends, and two ends of the second connecting member are connected in a one-to-one correspondence to two second free ends.

In some embodiments, the first support member is disposed on a portion of the first connecting member between the two first piezoelectric cantilevers in the second direction.

The second support member is disposed on a portion of the second connecting member between the two second piezoelectric cantilevers in the second direction.

In some embodiments, one first support member is disposed between the two first piezoelectric cantilevers, and the distance between the one first support member and each of the two first piezoelectric cantilevers in the second direction is equal.

Two second support members are spaced between two second piezoelectric cantilevers in the second direction. The two second piezoelectric cantilevers are in a one-to-one correspondence with the two second support members. The distance between one of the two second piezoelectric cantilevers and a respective one of the two second support members is a first distance, the distance between the other one of the two second piezoelectric cantilevers and a respective one of the two second support members is a second distance, and the first distance is equal to the second distance.

In some embodiments, the stiffness of the first connecting member is less than the stiffness of the first piezoelectric cantilever, and the stiffness of the second connecting member is less than the stiffness of the second piezoelectric cantilever.

In some embodiments, the first free end and the corresponding second free end are capable of synchronously vibrating in opposite vibration directions.

In some embodiments, the size of the first piezoelectric cantilever is equal to the size of the second piezoelectric cantilever in a third direction, and the third direction is perpendicular to the first direction and the second direction.

### BRIEF DESCRIPTION OF DRAWINGS

To illustrate the solutions in embodiments of the present disclosure more clearly, the drawings used in the description of the embodiments of the present disclosure are briefly described below. Apparently, the drawings described below illustrate only part of the embodiments of the present disclosure, and those of ordinary skill in the art may obtain other drawings based on the embodiments of the present disclosure and the drawings on the premise that no creative work is done.

FIG. 1 is a structure view of a loudspeaker according to one or more embodiments of the present disclosure;

FIG. 2 is an exploded view one of a loudspeaker according to one or more embodiments of the present disclosure;

FIG. 3 is an exploded view two of a loudspeaker according to one or more embodiments of the present disclosure;

FIG. 4 is a structure view of a part of a loudspeaker according to one or more embodiments of the present disclosure;

FIG. 5 is a front view of a loudspeaker according to one or more embodiments of the present disclosure;

FIG. 6 is a top view of a loudspeaker according to one or more embodiments of the present disclosure;

FIG. 7 is a section view taken along A-A in FIG. 6 of the present disclosure;

FIG. 8 is a section view taken along B-B in FIG. 6 of the present disclosure;

FIG. 9 is an exploded view one of a first piezoelectric cantilever according to one or more embodiments of the present disclosure;

FIG. 10 is a schematic diagram of a frequency response curve according to one or more embodiments of the present disclosure;

FIG. 11 is another structure view of a loudspeaker according to one or more embodiments of the present disclosure;

FIG. 12 is another exploded view of a part of a loudspeaker according to one or more embodiments of the present disclosure; and

FIG. 13 is an exploded view two of a first piezoelectric cantilever according to one or more embodiments of the present disclosure.

### REFERENCE LIST

100 support frame
110 first support
120 circuit board
130 second support
200 first diaphragm assembly
210 first diaphragm
220 first dome
300 second diaphragm assembly
310 second dome
320 second dome
400 first vibration assembly
410 first piezoelectric cantilever
411 first fixed end
412 first free end
413 first piezoelectric element
4131 first electrode layer
4132 second electrode layer
414 first substrate
500 second vibration assembly
510 second piezoelectric cantilever
511 second fixed end
512 second free end
513 second substrate
514 second piezoelectric element
600 first connecting member
610 hollow structure
700 first support member
800 second connecting member
900 second support member
X first direction
Y second direction
Z third direction

### DETAILED DESCRIPTION

To make the problems to be solved, the solutions to be adopted and the effects to be achieved by the present disclosure clearer, the solutions of the present disclosure are further described below through embodiments in conjunction with drawings. It is to be understood that the embodiments described herein are intended to explain the present disclosure and not to limit the present disclosure. In addition, it is to be noted that for ease of description, only a part, not all, related to the present disclosure is illustrated in the drawings.

It is to be noted that similar reference numerals and letters indicate similar items in the following drawings. Therefore, once a certain item is defined in one drawing, the similar reference numeral or letter does not need to be defined or explained in the subsequent drawings.

In the description of the present disclosure, unless otherwise expressly specified and limited, the terms “connected to each other”, “connected”, and “fixed” are to be understood in a broad sense, for example, as “fixedly connected”, “detachably connected”, or “integrated”; “mechanically connected” or “electrically connected”; “connected directly”, “connected indirectly via an intermediary”; “connected inside two elements” or “an interaction relation between two elements”. For those of ordinary skill in the art, specific meanings of the preceding terms in the present disclosure may be construed based on specific situations.

In the present disclosure, unless otherwise expressly specified and limited, a first feature being “above” or “below” a second feature may include that the first feature and the second feature may be in direct contact or may include that the first feature and the second feature are in contact via another feature between the two features instead of being in direct contact. Moreover, the first feature being “on”, “above” or “over” the second feature includes that the first feature is right or obliquely above the second feature or simply means that the first feature is at a higher level than the second feature. The first feature being “under”, “below” or “underneath” the second feature includes that the first feature is right or obliquely below the second feature or simply means that the first feature is at a lower level than the second feature. In the description of the embodiments, unless otherwise specified, “a plurality of”or “multiple”means two or more.

In the description of the embodiments, the orientation or position relationships indicated by the terms upper”, “lower”, “right”, and the like are based on the orientation or position relationships shown in the drawings. These orientations or position relations are intended only to facilitate and simplify the description of the present disclosure and not to indicate or imply that a device or element referred to must have such particular orientations or must be configured or operated in such particular orientations. Thus, these orientations or position relations are not to be construed as limiting the present disclosure. In addition, the terms “first” and “second” are merely used for descriptive purposes and have no special meanings.

It is to be noted that when an element is described as being “fixed to” or “disposed on” another element, the element may be directly on the particular element or an intervening element may be on the particular element.

The embodiments provide a loudspeaker. The loudspeaker can be applied to an electronic device and can have a flat frequency response curve, a good acoustic effect, and great acoustic performance.

The loudspeaker in the embodiments may be a micro-electromechanical system (MEMS) loudspeaker. The MEMS loudspeakers can be widely used in current mobile electronic devices due to their advantages of low power consumption and light weight.

It is to be noted that the electronic devices may include mobile phones, tablet personal computers, laptops, personal digital assistants (PDA), cameras, personal computers, notebook computers, in-vehicle devices, wearable devices, augmented reality (AR) glasses, AR helmets, virtual reality (VR) glasses, VR helmets, fixed-line earpieces (sound pick-ups), medical auxiliary devices (for example, hearing aids), various headphones (for example, wireless or wired headphones), and other devices equipped with loudspeakers. The embodiments of the present application do not impose any special limitations on the specific form of the above electronic devices.

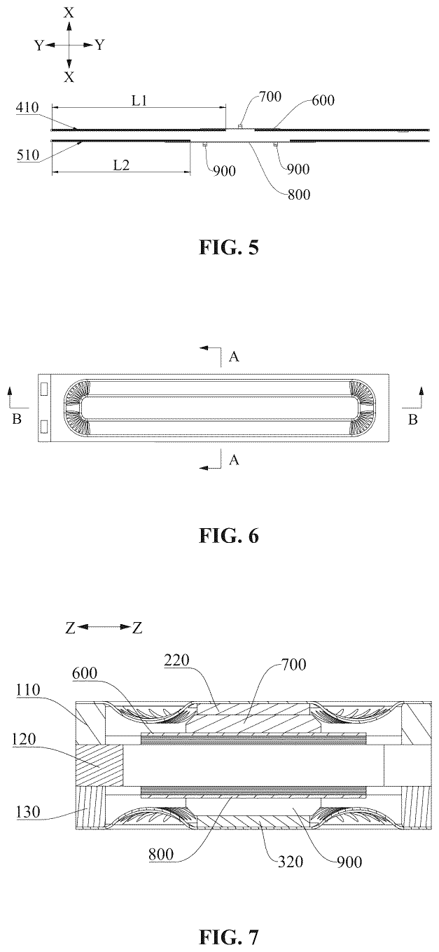

Before the description of the embodiment, a three-dimensional coordinate system may be established in some of the drawings for the convenience of the following description. With an example where the loudspeaker shown in FIG. 6 is a rectangle, as shown in FIG. 5, the first direction X is the thickness direction of the loudspeaker, and the second direction Y is the length direction of the loudspeaker; as shown in FIG. 7, the third direction Z is the width direction of the loudspeaker; that is, any two of the first direction X, the second direction Y or the third direction Z are perpendicular to each other. It is to be understood that the width direction of the loudspeaker is less than the length direction of the loudspeaker.

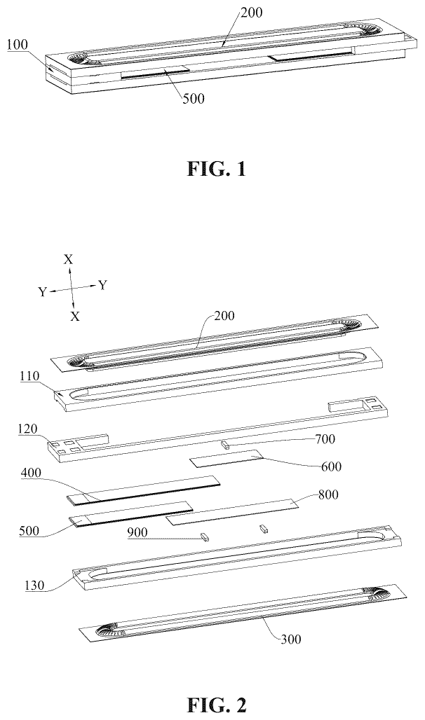

As shown in FIGS. 1 to 9, the loudspeaker includes a support frame 100, a first diaphragm assembly 200, a second diaphragm assembly 300, a first vibration assembly 400, and a second vibration assembly 500.

For example, the support frame 100 is made of a hard material such as metal, plastic, and the like.

For example, the support frame 100 has a frame structure, and the support frame 100 has a cavity extending through both surfaces of the support frame 100 in the first direction X. The support frame 100 may be a separate piece, or, the support frame 100 may be an integral piece.

For example, as shown in FIGS. 2 and 3, the support frame 100 includes a first support 110, a circuit board 120, and a second support 130 which are sequentially connected in the first direction X. The cavity extends through the first support 110, the circuit board 120, and the second support 130. The circuit board 120 is used for being electrically connected to the first vibration assembly 400 and the second vibration assembly 500 to supply acousto-electric signals to the first vibration assembly 400 and the second vibration assembly 500.

For example, the circuit board 120 may be provided with a weld disc (not shown), and the first vibration assembly 400 and the second vibration assembly 500 are welded to the weld disc to achieve the electrical connection between the first vibration assembly 400 and the second vibration assembly 500.

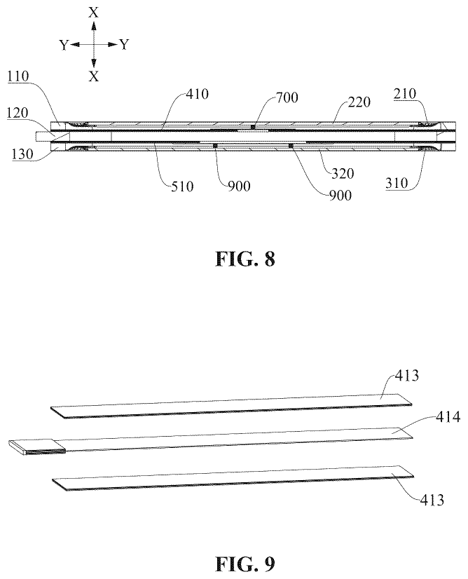

As shown in FIG. 1, the first diaphragm assembly 200 is disposed in the support frame 100, specifically, on one side surface of the support frame 100 in the first direction X. For the specific structure of the first diaphragm assembly 200, reference may be made to the related art. For example, as shown in FIG. 8, the first diaphragm assembly 200 includes a first diaphragm 210 connected to the support frame 100 and a first dome 220 disposed on one side, facing the support frame 100, of the first diaphragm 210.

The second diaphragm assembly 300 is disposed in the support frame 100 and opposite the first diaphragm assembly 200 in the first direction X. Specifically, the second diaphragm assembly 300 is disposed on the other side surface of the support frame 100 in the first direction X, and the first diaphragm assembly 200, the support frame 100, and the second vibration assembly 500 can enclose an acoustic cavity. The support frame 100 is provided with an acoustic hole in communication with the acoustic hole. For the specific structure of the second diaphragm assembly 300, reference may be made to the related art. For example, as shown in FIG. 8, the second diaphragm assembly 300 includes a second diaphragm 310 connected to the support frame 100 and a second dome 320 disposed on a side, facing the support frame 100, of the second diaphragm 310.

For example, the first vibration assembly 400 and the second vibration assembly 500 are both disposed between the first diaphragm assembly 200 and the second diaphragm assembly 300 in the first direction X. The first vibration assembly 400 is closer to the first diaphragm assembly 200 than the second vibration assembly 500, that is, the second vibration assembly 500 is disposed between the second diaphragm assembly 300 and the first vibration assembly 400 in the first direction X.

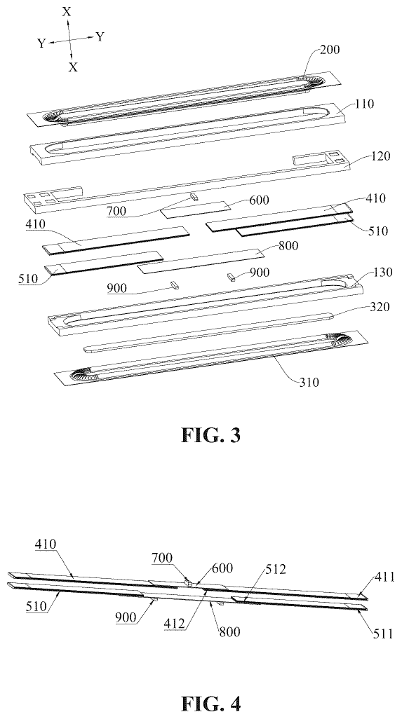

With reference to FIG. 3, the first vibration assembly 400 includes a first piezoelectric cantilever 410. As shown in FIG. 4, the first piezoelectric cantilever 410 includes a first fixed end 411 and a first free end 412 facing away from the first fixed end 411. The first fixed end 411 is connected to the support frame 100. For example, the first fixed end 411 is electrically connected to the circuit board 120, and the circuit board 120 and the first support 110 cooperate with each other to clamp the first fixed end 411. The first free end 412 is suspended inside the support frame 100 and connected to the first diaphragm assembly 200. The first fixed end 411 of the first piezoelectric cantilever 410 is electrically connected to the circuit board 120, the circuit board 120 inputs an acousto-electric signal to the first piezoelectric cantilever 410, the first piezoelectric cantilever 410 then bends, and the first free end 412 vibrates relative to the first fixed end 411, that is, the first free end 412 vibrates relative to the support frame 100. The first free end 412 of the first piezoelectric cantilever 410 vibrates and drives the first diaphragm assembly 200 to vibrate.

With continued reference to FIG. 3, the second vibration assembly 500 includes a second piezoelectric cantilever 510. With continued reference to FIG. 4, the second piezoelectric cantilever 510 includes a second fixed end 511 and a second free end 512 facing away from the second fixed end 511. The second fixed end 511 is connected to the support frame 100. For example, the second fixed end 511 is connected to the circuit board 120, and the circuit board 120 and the second support 130 cooperate with each other to clamp the second fixed end 511. The second free end 512 is suspended inside the support frame 100 and connected to the second diaphragm assembly 300. The second fixed end 511 of the second piezoelectric cantilever 511 is electrically connected to the circuit board 120, the circuit board 120 inputs an acousto-electric signal to the second piezoelectric cantilever 510, the second piezoelectric cantilever 510 then bends, and the second free end 512 vibrates relative to the second fixed end 511, that is, the second free end 512 vibrates relative to the support frame 100. The second free end 512 of the second piezoelectric cantilever 510 vibrates and drives the second diaphragm assembly 300 to vibrate.

The beneficial effects of the present disclosure are as follows.

Due to different lengths of the first piezoelectric cantilever and the second piezoelectric cantilever in the second direction, the frequency point of the vibration mode corresponding to the first piezoelectric cantilever is different from the frequency point of the vibration mode corresponding to the second piezoelectric cantilever, and the frequency point of the vibration mode corresponding to the first piezoelectric cantilever is staggered from the frequency point of the vibration mode corresponding to the second piezoelectric cantilever. Therefore, the occurrence of the situation in which the superimposed frequency points of the vibration modes are either very high or very low is avoided, and the probability that the overall frequency response curve has a large number of peaks and valleys is reduced, thereby enabling the overall frequency response curve to be relatively flat and achieving great acoustic performance and a good acoustic effect.

For example, the direction in which the first fixed end 411 extends to the first free end 412 is same as the direction in which the second fixed end 511 extends to the second free end 512. In this manner, the first piezoelectric cantilever 410 may be substantially rectangular, and the second piezoelectric cantilever 510 may be substantially rectangular. The first piezoelectric cantilever 410 and the second piezoelectric cantilever 510 can fully utilize the inner space of the support frame 100 and make the structures of the first vibration assembly 400 and the second vibration assembly 500 simple and easy to process. In some other embodiments, the first piezoelectric cantilever 410 and the second piezoelectric cantilever 510 may also have an irregular structure such as an L-shaped structure, a Z-shaped structure, a T-shaped structure, and a trapezoidal structure, which is not limited herein.

In the embodiments, as shown in FIG. 5, the first piezoelectric cantilever 410 and the second piezoelectric cantilever 510 are disposed opposite each other in the first direction X, and the length of the first piezoelectric cantilever 410 in the second direction Y is different from the length of the second piezoelectric cantilever 510 in the second direction Y, that is, the length of the first piezoelectric cantilever 410 in the second direction Y is greater than or equal to the length of the second piezoelectric cantilever 510 in the second direction Y. The second direction Y is a direction perpendicular to the direction in which the first piezoelectric cantilever 410 vibrates or the direction in which the second piezoelectric cantilever 510 vibrates. Due to different lengths of the first piezoelectric cantilever 410 and the second piezoelectric cantilever 510 in the second direction Y, the frequency point of the vibration mode corresponding to the first piezoelectric cantilever 410 is different from the frequency point of the vibration mode corresponding to the second piezoelectric cantilever 510. For example, the frequency point of the vibration mode corresponding to the first piezoelectric cantilever 410 is staggered from the frequency point of the vibration mode corresponding to the second piezoelectric cantilever 510. Therefore, the occurrence of the situation in which the superimposed frequency points of the vibration modes are either very high or very low is avoided, and the probability that the overall frequency response curve has a large number of peaks and valleys is reduced, thereby enabling the overall frequency response curve to be relatively flat and achieving great acoustic performance and a good acoustic effect.

It is to be noted that the length of a portion of the first piezoelectric cantilever 410 fixed on the support frame 100 is equal to the length of a portion of the second piezoelectric cantilever 510 fixed on the support frame 100, and the setting that the length of the first piezoelectric cantilever 410 in the second direction Y is different from the length of the second piezoelectric cantilever 510 in the second direction Y specifically embodied in that, in the second direction Y, the length of the portion of the first piezoelectric cantilever 410 that is suspended in the support frame 100 is different from the length of the portion of the second piezoelectric cantilever 510 that is suspended in the support frame 100.

For example, as shown in FIG. 2, one first piezoelectric cantilever 410 and one second piezoelectric cantilever 510 are disposed.

Of course, it is to be understood that multiple first piezoelectric cantilevers 410 and multiple second piezoelectric cantilevers 510 may also be disposed in a one-to-one correspondence in the loudspeaker, and the multiple first piezoelectric cantilevers 410 are disposed in the same layer and spaced from each other, that is, the multiple first piezoelectric cantilevers 410 are disposed in the same layer, and a spacing exists between two adjacent first piezoelectric cantilevers 410 in a direction perpendicular to the first direction X, thereby avoiding the mutual interference among the first free ends 412.

Similarly, the multiple second piezoelectric cantilevers 510 are disposed in the same layer and spaced from each other, that is, the multiple second piezoelectric cantilevers 510 are disposed in the same layer, and a spacing exists between two adjacent second piezoelectric cantilevers 510 in a direction perpendicular to the first direction X, thereby avoiding the mutual interference among the second free ends 512.

By setting multiple second piezoelectric cantilevers 510 and multiple first piezoelectric cantilevers 410, the sensitivity of the loudspeaker can be improved.

It is to be noted that the multiple first piezoelectric cantilevers 410 all have the same length in the second direction Y, and the multiple second piezoelectric cantilevers 510 all have the same length in the second direction Y. In this manner, the acousto-electric signal of the same frequency can be simultaneously input to multiple first fixed ends 411 to enable multiple first free ends 412 to synchronously vibrate in the same direction, the acousto-electric signal of the same frequency can be simultaneously input to multiple second fixed ends 511 to enable multiple second free ends 512 to synchronously vibrate in the same direction, and in addition, the first piezoelectric cantilevers 410 and the second piezoelectric cantilevers 510 can be manufactured conveniently in batches.

Optionally, multiple first piezoelectric cantilevers 410 and multiple second piezoelectric cantilevers 510 are disposed in a one-to-one correspondence in the loudspeaker, and each first piezoelectric cantilever 410 and a respective one second piezoelectric cantilever 510 are disposed opposite each other in the first direction X. For example, the orthographic projection of a first piezoelectric cantilever 410 in the plane where the support frame 100 is located at least partially overlaps the orthographic projection of the respective one second piezoelectric cantilever 510 in the plane where the support frame 100 is located. Moreover, the length of the first piezoelectric cantilever 410 in the second direction Y is different from the length of the respective one second piezoelectric cantilever 510 in the second direction Y so that the frequency points of the vibration modes in the combination structure consisting of the first piezoelectric cantilever 410 and the respective one second piezoelectric cantilever 510 are staggered from each other and the frequency points of the vibration modes in multiple combination structures are simultaneously staggered from each other. Therefore, the probability that the overall frequency response curve has a large number of peaks and valleys is reduced while the loudspeaker has high sensitivity, thereby enabling the overall frequency response curve to be relatively flat and achieving great acoustic performance and a good acoustic effect.

For example, as shown in FIG. 3, two first piezoelectric cantilevers 410 and two second piezoelectric cantilevers 510 are disposed in a one-to-one correspondence in the loudspeaker, the two first piezoelectric cantilevers 410 are spaced in the second direction Y, and the two second piezoelectric cantilevers 510 are spaced in the second direction Y. The length of a first piezoelectric cantilever 410 in the second direction Y is greater than or equal to the length of the respective one second piezoelectric cantilever 510 in the second direction Y. In the embodiments, as shown in FIG. 5, the length of the first piezoelectric cantilever 410 in the second direction Y is L1, the length of the second piezoelectric cantilever 510 in the second direction Y is L2, and L1>L2.

Optionally, as shown in FIG. 2 or 3, the loudspeaker further includes a first connecting member 600, a second connecting member 800, a first support member 700, and a second support member 900.

One end of the first connecting member 600 is connected to the first free end 412, and the first support member 700 is connected between the first connecting member 600 and the first diaphragm assembly 200 so that the first piezoelectric cantilever 410 is connected to the first diaphragm assembly 200 through the first connecting member 600 and the first support member 700. In some optional embodiments, the first support member 700 is connected to the first dome 220 of the first diaphragm assembly 200.

In some optional embodiments, the stiffness of the first connecting member 600 is less than the stiffness of the first piezoelectric cantilever 410. It is to be noted that the stiffness refers to the ability of a material or structure to resist elastic deformation in response to an applied force. The greater the stiffness of a structure is, which means that the ability of the structure to resist elastic deformation in response to an applied force is relatively high, the less elastic the structure is. In the embodiments, the stiffness of the first piezoelectric cantilever 410 is greater than the stiffness of the first connecting member 600, that is, the rigidity of the first piezoelectric cantilever 410 is greater than the rigidity of the first connecting member 600, so that the elasticity of the first connecting member 600 is greater than the elasticity of the first piezoelectric cantilever 410.

It is further to be noted that the stiffness of the first connecting member 600 in the vibration direction (that is, the first direction X) of the first piezoelectric cantilever 410 is less than the stiffness of the first piezoelectric cantilever 410 in its vibration direction.

By setting the first connecting member 600 and the first support member 700, the first free end 412 of the first piezoelectric cantilever 410 is not directly connected to the first support member 700 but is connected to the first support member 700 through the first connecting member 600. By setting the stiffness of the first connecting member 600 to be less than the stiffness of the first piezoelectric cantilever 410, the first connecting member 600 has a certain degree of elasticity compared to the first piezoelectric cantilever 410. The existence of the first connecting member 600 can prevent the amplitude of the first diaphragm assembly 200 from a drastic change in a short period of time so that the first diaphragm assembly 200 is not prone to damage when the first connecting member 600 drives the first diaphragm assembly 200 to vibrate through the first support member 700, thereby improving the reliability of the loudspeaker and prolonging the service life of the loudspeaker.

Similarly, one end of the second connecting member 800 is connected to the second free end 512, and the second support member 900 is connected between the second connecting member 800 and the second diaphragm assembly 300 so that the second piezoelectric cantilever 510 is connected to the second diaphragm assembly 300 through the second connecting member 800 and the second support member 900. In some optional embodiments, the second support member 900 is connected to the second dome 320 of the second diaphragm assembly 300.

Further, optionally, the stiffness of the second connecting member 800 is less than the stiffness of the second piezoelectric cantilever 510. In the embodiments, the stiffness of the second piezoelectric cantilever 510 is greater than the stiffness of the second connecting member 800, that is, the rigidity of the second piezoelectric cantilever 510 is greater than the rigidity of the second connecting member 800, so that the elasticity of the second connecting member 800 is greater than the elasticity of the second piezoelectric cantilever 510.

By setting the second connecting member 800 and the second support member 900, the second free end 512 of the second piezoelectric cantilever 510 is not directly connected to the second support member 900 but is connected to the second support member 900 through the second connecting member 800. By setting the stiffness of the second connecting member 800 to be less than the stiffness of the second piezoelectric cantilever 510, the second connecting member 800 has a certain degree of elasticity compared to the second piezoelectric cantilever 510. The existence of the second connecting member 800 can prevent the amplitude of the second diaphragm assembly 300 from a drastic change in a short period of time so that the second diaphragm assembly 300 is not prone to damage when the second connecting member 800 drives the second diaphragm assembly 300 to vibrate through the second support member 900, thereby improving the reliability of the loudspeaker and prolonging the service life of the loudspeaker.

For example, the materials of the first connecting member 600 and the second connecting member 800 include, but are not limited to, metal materials, polymer materials, and the like, as long as their best performance can be achieved. For example, the first connecting member 600 and the second connecting member 800 are made of polyimide (PI).

For example, the first support member 700 and the second support member 900 are both made of a hard material such as metal, plastic, and the like to enable the transmission of power and motion to be efficient and accurate. The first support member 700 and the second support member 900 may both be made of a lightweight material such as lightweight metal and the like to reduce the resistance of transmission and improve the sensitivity of the transmission of power and motion.

When two first piezoelectric cantilevers 410 and two second piezoelectric cantilevers 510 are disposed in a one-to-one correspondence in the loudspeaker, two ends of the first connecting member 600 are connected in a one-to-one correspondence to two first free ends 412 so that the two first piezoelectric cantilevers 410 are connected to each other through the first connecting member 600, thereby reducing the number of the required first connecting members 600 and achieving multiple functions of the first connecting member 600.

Similarly, two ends of the second connecting member 800 are connected in a one-to-one correspondence to two second free ends 512 so that the two second piezoelectric cantilevers 510 are connected to each other through the second connecting member 800, thereby reducing the number of the required second connecting members 800 and achieving multiple functions of the second connecting member 800.

Optionally, the first support member 700 is disposed on a portion of the first connecting member 600 between the two first piezoelectric cantilevers 410 in the second direction Y, that is, the first support member 700 and the first piezoelectric cantilever 410 are staggered in the second direction Y, thereby preventing the first support member 700 from being in hard contact with the first diaphragm assembly 200 under the push of the first piezoelectric cantilever 410 with large rigidity, further reducing the probability of damage to the first diaphragm assembly 200, and prolonging the service life of the loudspeaker.

Similarly, the second support member 900 is disposed on a portion of the second connecting member 800 between the two second piezoelectric cantilevers 510 in the second direction Y, that is, the second support member 900 and the second piezoelectric cantilever 510 are staggered in the second direction Y, thereby preventing the second support member 900 from being in hard contact with the second diaphragm assembly 300 under the push of the second piezoelectric cantilever 510 with large rigidity, further reducing the probability of damage to the second diaphragm assembly 300, and prolonging the service life of the loudspeaker.

For example, the number of first support members 700 may be determined according to the spacing between the two first piezoelectric cantilevers 410 in the second direction Y. If the spacing is large, the arm of force is large, and thus, multiple first support members 700 may be disposed. Similarly, the number of second support members 900 may be determined according to the spacing between the two second piezoelectric cantilevers 510 in the second direction Y. If the spacing is large, the arm of force is large, and thus, multiple second support members 900 may be disposed.

For example, as shown in FIG. 5, the length of the first piezoelectric cantilever 410 in the second direction Y is greater than the length of the second piezoelectric cantilever 510 in the second direction Y, the two first piezoelectric cantilevers 410 have identical shape and size, the two second piezoelectric cantilevers 510 have identical shape and size, and thus, the spacing between the two first piezoelectric cantilevers 410 in the second direction Y is less than the spacing between the two second piezoelectric cantilevers 510 in the second direction Y.

Further, optionally, one first support member 700 is disposed between the two first piezoelectric cantilevers 410, and the distance (or the minimum distance) between the first support member 700 and each of the two first piezoelectric cantilevers 410 in the second direction Y is equal, that is, the first support member 700 is centrally disposed. In this manner, the driving effect and the driving precision on the first diaphragm assembly 200 can be guaranteed, and a symmetrical structure can be formed, thereby ensuring the symmetry of the loudspeaker as a whole and preventing the loudspeaker from violently vibrating due to the center-of-gravity shift.

For example, with continued reference to FIG. 5, two second support members 900 are spaced between two second piezoelectric cantilevers 510 in the second direction Y. The minimum distance between one second piezoelectric cantilever 510 of the two second piezoelectric cantilevers 510 and the second support member 900 correspondingly proximate to the one second piezoelectric cantilever 510 in the second direction Y is equal to a minimum distance between the other one second piezoelectric cantilever 510 of the two second piezoelectric cantilevers 510 and the second support member 900 correspondingly proximate to the other one second piezoelectric cantilever 510 in the second direction Y, that is, the two second piezoelectric cantilevers 510 are in a one-to-one correspondence with the two second support members 900, the distance between one of the two second piezoelectric cantilevers 510 and a respective one of the two second support members 900 is a first distance, the distance between the other one of the two second piezoelectric cantilevers 510 and a respective one of the two second support members 900 is a second distance, and the first distance is equal to the second distance. Through the above setting, the multiple second free ends 512 can synchronously vibrate in the same direction to enable the vibration on the two second free ends 512 to be transmitted to the two second support members 900 at the same time and in turn enable the second support members 900 to synchronously drive the second diaphragm assembly 300 in the same direction.

In some optional embodiments, the multiple first free ends 412 can synchronously vibrate in the same direction to enable the forces transmitted from the multiple first free ends 412 to the first diaphragm assembly 200 to be in the same direction, thereby avoiding the forces cancelling each other out. For example, the circuit board 120 inputs identical acousto-electric signals to the multiple first piezoelectric cantilevers 410 to ensure that the multiple first free ends 412 can synchronously vibrate in the same direction.

Optionally, the first free end 412 and the corresponding second free end 512 can synchronously vibrate in opposite directions to enable the vibration of the first free end 412 and the vibration of the second free end 512 to cancel each other out and in turn enable the vibration of the first piezoelectric cantilever 410 and the second piezoelectric cantilever 510 to cancel each other out. In this manner, the loudspeaker does not vibrate or the vibration of the loudspeaker is weakened, thereby achieving the purpose of vibration reduction, reducing the impact of the vibration of the loudspeaker on the electronic device, and improving the user experience.

In some optional embodiments, the size of the first piezoelectric cantilever 410 is equal to the size of the second piezoelectric cantilever 510 in a third direction Z, that is, the first piezoelectric cantilever 410 and the second piezoelectric cantilever 510 are of equal width. In this manner, the degree to which the vibrations on the first piezoelectric cantilever 410 and the second piezoelectric cantilever 510 cancel each other out can be further improved, and the vibration of the loudspeaker can be further weakened, thereby achieving the purpose of vibration reduction and further reducing the impact of the vibration of the loudspeaker on the electronic device.

In some optional embodiments, the circuit board 120 may input acousto-electric signals of equal size and frequency but opposite amplitude to the first piezoelectric cantilever 410 and the second piezoelectric cantilever 510 respectively to enable the first piezoelectric cantilever 410 and the second piezoelectric cantilever 510 to vibrate at the same amplitude but in opposite directions, thereby enabling the first free end 412 and the corresponding second free end 512 to synchronously vibrate in opposite directions.

Optionally, as shown in FIGS. 9 and 11 to 13, the first piezoelectric cantilever 410 may include a first substrate 414 and a first piezoelectric element 413 disposed on at least one side of the first substrate 414 in the thickness direction (that is, the first direction X) of the first substrate 414.

In some optional embodiments, one end of the first substrate 414 is connected to the support frame 100, and the other end of the first substrate 414 is suspended inside the support frame 100 to form a free end. The first piezoelectric element 413 is disposed on the surface, facing the first diaphragm assembly 200, of the first substrate 414, and the first connecting member 600 is connected to the first piezoelectric element 413.

In some optional embodiments, the first substrate 414 is provided with the first piezoelectric element 413 on both the upper and lower surfaces of the first substrate 414 in the first direction X, and the first piezoelectric element 413 facing the surface of the first diaphragm assembly 200 is connected to the first connecting member 600.

In some other optional embodiments, one end of the first substrate 414 is connected to the support frame 100, and the other end of the first substrate 414 extends in a direction facing away from the support frame 100 and forms the first connecting member 600, that is, the first connecting member 600 is connected to the first substrate 414 and the first substrate 414 and the first connecting member 600 are integrally formed.

Optionally, the area of the first piezoelectric element 413 may be equal to the area of the first substrate 414 or may be less than the area of the first substrate 414. The first piezoelectric element 413 may drive the first substrate 414 to vibrate in the thickness direction of the first piezoelectric cantilever 410. For example, the first piezoelectric element 413 may be any of a piezoelectric driver, an electrostatic driver, an electromagnetic driver or a thermoelectric driver.

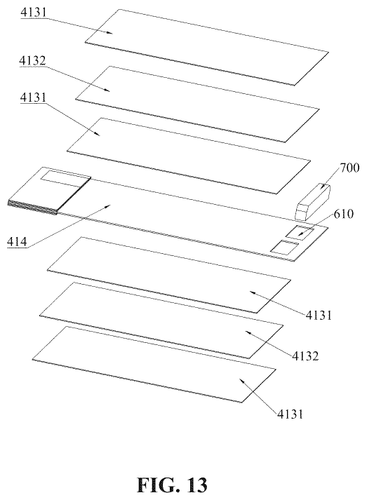

For example, as shown in FIG. 13, the first piezoelectric element 413 includes one or more first electrode layers 4131 and one or more second electrode layers 4132 that are stacked. The polarity of the first electrode layer 4131 is opposite to the polarity of the second electrode layer 4132. At least one first electrode layer 4131 and at least one second electrode layer 4132 may be disposed and are staggered in the stacked direction. For example, in the embodiments, the first electrode layers 4131 are in contact with the first substrate 414, the number of first electrode layers 4131 disposed is two, and the number of second electrode layers 4132 disposed is one.

Similarly, as shown in FIGS. 11 to 13, the second piezoelectric cantilever 510 may include a second substrate 513 and a second piezoelectric element 513 disposed on at least one side of the second substrate 513 in the thickness direction (that is, the first direction X) of the second substrate 513.

In some optional embodiments, one end of the second substrate 513 is connected to the support frame 100, and the other end of the second substrate 513 is suspended inside the support frame 100 to form a free end. The second piezoelectric element 514 is disposed on the surface, facing the second diaphragm assembly 300, of the second substrate 513, and the second connecting member 800 is connected to the second piezoelectric element 514. In some other optional embodiments, one end of the second substrate 513 is connected to the support frame 100, and the other end of the second substrate 513 extends in the direction facing away from the support frame 100 and forms the second connecting member 800, that is, the second connecting member 800 is connected to the second substrate 513 and the second substrate 513 and the second connecting member 800 are integrally formed.

Optionally, the area of the second piezoelectric element 514 may be equal to the area of the second substrate 513 or may be less than the area of the second substrate 513. The second piezoelectric element 514 may drive the second substrate 513 to vibrate in the thickness direction of the second piezoelectric cantilever 510. For example, the second piezoelectric element 514 may be any of a piezoelectric driver, an electrostatic driver, an electromagnetic driver or a thermoelectric driver.

Optionally, the specific structure of the second piezoelectric element 514 may be the same as or similar to the specific structure of the first piezoelectric element 413, which is not limited herein.

In some optional embodiments, as shown in FIG. 13, a hollow structure 610 (for example, a hollow hole) may be disposed on the first connecting member 600 and/or the second connecting member 800. With the setting of the hollow structure 610, the weight of the first connecting member 600 and the second connecting member 800 can be reduced. The first support member 700 is disposed in a region where the hollow structure 610 is not disposed in the first connecting member 600, and the second support member 900 is disposed in a region where the hollow structure 610 is not disposed in the second connecting member 800.

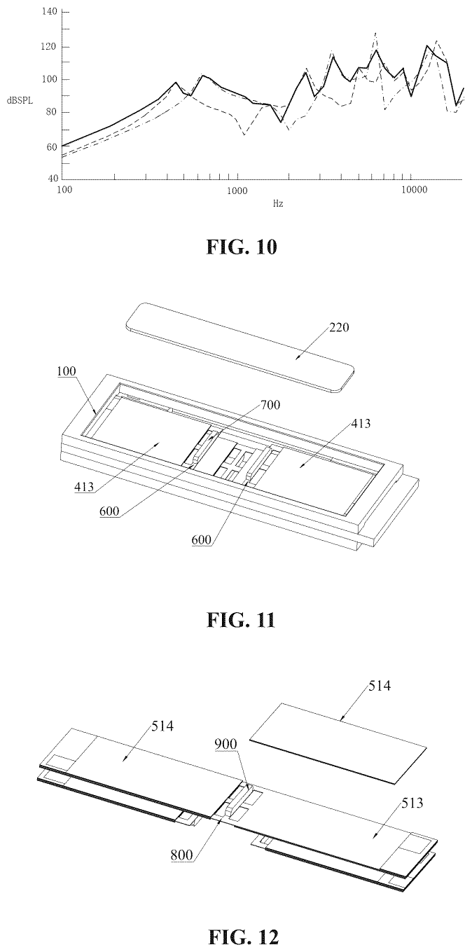

With reference to FIG. 10, the solid line in FIG. 10 represents the frequency response curve of the loudspeaker provided in the embodiments. The horizontal coordinate in the figure is the frequency in Hz, and the vertical coordinate is the sound pressure level (SPL) in dB. The specific structure of the loudspeaker is the structure shown in FIG. 3, that is, the loudspeaker includes two first piezoelectric cantilevers 410 and two second piezoelectric cantilevers 510, and the length of the first piezoelectric cantilever 410 in the second direction Y is greater than the length of the second piezoelectric cantilever 510 in the second direction Y.

The dotted line in FIG. 10 represents a frequency response curve of a loudspeaker in the related art, and such a loudspeaker includes multiple first piezoelectric cantilevers 410 only and does not include any second piezoelectric cantilever 510.

The dot-and-dash line in FIG. 10 represents a frequency response curve of another loudspeaker in the related art, and such a loudspeaker includes a second piezoelectric cantilever 510 only and does not include any first piezoelectric cantilever 410.

As can be seen from FIG. 10, the frequency response curve of the loudspeaker provided in the embodiments is flatter, with a smaller difference between the maximum peak and the maximum valley, and thus has a better acoustic effect.

It is to be noted that the preceding are only preferred embodiments of the present disclosure and the principles used therein. It is to be understood by those skilled in the art that the present disclosure is not limited to the embodiments described herein. Those skilled in the art can make various apparent modifications, adaptations, and substitutions without departing from the scope of the present disclosure. Therefore, while the present disclosure is described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A loudspeaker, comprising
a support frame;
a first diaphragm assembly, disposed in the support frame;
a second diaphragm assembly, disposed in the support frame and opposite the first diaphragm assembly in a first direction;
a first vibration assembly, wherein the first vibration assembly is located between the first diaphragm assembly and the second diaphragm assembly in the first direction and comprises a first piezoelectric cantilever, the first piezoelectric cantilever comprises a first fixed end and a first free end, the first fixed end is connected to the support frame, and the first free end is suspended inside the support frame and connected to the first diaphragm assembly; and
a second vibration assembly, wherein the second vibration assembly is located between the second diaphragm assembly and the first vibration assembly in the first direction and comprises a second piezoelectric cantilever, the second piezoelectric cantilever comprises a second fixed end and a second free end, the second fixed end is connected to the support frame, and the second free end is suspended inside the support frame and connected to the second diaphragm assembly;
wherein the first piezoelectric cantilever and the second piezoelectric cantilever are disposed opposite each other in the first direction, a length of the first piezoelectric cantilever in a second direction is different from a length of the second piezoelectric cantilever in the second direction, and the second direction is perpendicular to the first direction.

2. The loudspeaker according to claim 1, wherein a plurality of first piezoelectric cantilevers and a plurality of second piezoelectric cantilevers are disposed in a one-to-one correspondence in the loudspeaker, the plurality of first piezoelectric cantilevers are disposed in a same layer and spaced from each other, and the plurality of second piezoelectric cantilevers are disposed in a same layer and spaced from each other;
a first piezoelectric cantilever of the plurality of first piezoelectric cantilevers and a respective one of the plurality of second piezoelectric cantilevers are disposed opposite each other in the first direction, and a length of the first piezoelectric cantilever of the plurality of first piezoelectric cantilevers in the second direction is different from a length of the respective one of the plurality of second piezoelectric cantilevers in the second direction.

3. The loudspeaker according to claim 1, wherein two first piezoelectric cantilevers and two second piezoelectric cantilevers are disposed in a one-to-one correspondence in the loudspeaker, the two first piezoelectric cantilevers are spaced in the second direction, and the two second piezoelectric cantilevers are spaced the second direction.

4. The loudspeaker according to claim 3, further comprising a first connecting member, a first support member, a second connecting member, and a second support member;
wherein one end of the first connecting member is connected to the first free end, and the first support member is connected between the first connecting member and the first diaphragm assembly; and
one end of the second connecting member is connected to the second free end, and the second support member is connected between the second connecting member and the second diaphragm assembly.

5. The loudspeaker according to claim 4, wherein the first piezoelectric cantilever comprises a first substrate and a first piezoelectric element disposed on at least one side of the first substrate in a thickness direction of the first substrate; one end of the first substrate is connected to the support frame, and the first connecting member is connected to one end of the first piezoelectric element facing away from the support frame; and
the second piezoelectric cantilever comprises a second substrate and a second piezoelectric element disposed on at least one side of the second substrate in a thickness direction of the second substrate; one end of the second substrate is connected to the support frame, and the second connecting member is connected to one end of the second piezoelectric element facing away from the support frame.

6. The loudspeaker according to claim 4, wherein the first piezoelectric cantilever comprises a first substrate and a first piezoelectric element disposed on at least one side of the first substrate in a thickness direction of the first substrate; one end of the first substrate is connected to the support frame, and the other end of the first substrate extends in a direction facing away from the support frame and forms the first connecting member; and
the second piezoelectric cantilever comprises a second substrate and a second piezoelectric element disposed on at least one side of the second substrate in a thickness direction of the second substrate; one end of the second substrate is connected to the support frame, and the other end of the second substrate extends in the direction facing away from the support frame and forms the second connecting member.

7. The loudspeaker according to claim 4, wherein two ends of the first connecting member are connected in a one-to-one correspondence to two first free ends, and two ends of the second connecting member are connected in a one-to-one correspondence to two second free ends.

8. The loudspeaker according to claim 7, wherein the first support member is disposed on a portion of the first connecting member between the two first piezoelectric cantilevers in the second direction;
the second support member is disposed on a portion of the second connecting member between the two second piezoelectric cantilevers in the second direction.

9. The loudspeaker according to claim 8, wherein one first support member is disposed between the two first piezoelectric cantilevers, and a distance between the one first support member and each of the two first piezoelectric cantilevers in the second direction is equal;
two second support members are spaced between two second piezoelectric cantilevers in the second direction, the two second piezoelectric cantilevers are in a one-to-one correspondence with the two second support members; and
a distance between one of the two second piezoelectric cantilevers and a respective one of the two second support members is a first distance, a distance between the other one of the two second piezoelectric cantilevers and a respective one of the two second support members is a second distance, and the first distance is equal to the second distance.

10. The loudspeaker according to claim 5, wherein a stiffness of the first connecting member is less than a stiffness of the first piezoelectric cantilever, and a stiffness of the second connecting member is less than a stiffness of the second piezoelectric cantilever.

11. The loudspeaker according to claim 1, wherein the first free end and a corresponding second free end are capable of synchronously vibrating in opposite vibration directions.

12. The loudspeaker according to claim 11, wherein a size of the first piezoelectric cantilever is equal to a size of the second piezoelectric cantilever in a third direction, and the third direction is perpendicular to the first direction and the second direction.

13. The loudspeaker according to claim 2, wherein the first free end and a corresponding second free end are capable of synchronously vibrating in opposite vibration directions.

14. The loudspeaker according to claim 3, wherein the first free end and a corresponding second free end are capable of synchronously vibrating in opposite vibration directions.

15. The loudspeaker according to claim 4, wherein the first free end and a corresponding second free end are capable of synchronously vibrating in opposite vibration directions.

16. The loudspeaker according to claim 5, wherein the first free end and a corresponding second free end are capable of synchronously vibrating in opposite vibration directions.

17. The loudspeaker according to claim 6, wherein the first free end and a corresponding second free end are capable of synchronously vibrating in opposite vibration directions.

18. The loudspeaker according to claim 7, wherein the first free end and a corresponding second free end are capable of synchronously vibrating in opposite vibration directions.

19. The loudspeaker according to claim 8, wherein the first free end and a corresponding second free end are capable of synchronously vibrating in opposite vibration directions.

20. The loudspeaker according to claim 9, wherein the first free end and a corresponding second free end are capable of synchronously vibrating in opposite vibration directions.
